(19) United States
(12) Patent Application Publication
(10) Pub. No.: US 2025/0309576 A1
(43) Pub. Date: Oct. 2, 2025

(54) MECHANICAL DESIGN AND ELECTRICAL FUNCTIONALITY OF SPRING-LOADED PINS

(71) Applicant: Google LLC, Mountain View, CA (US)

(72) Inventors: Chao Hu, Dongguan (CN); Wing Tung Wong, Sunnyvale, CA (US); Farzam Sajed, Santa Clara, CA (US); Wenson Chern, San Jose, CA (US); Vivek Saini, Sunnyvale, CA (US); Valentin Shaun de la Fuente, San Francisco, CA (US); Juan Manuel Fantin, Mountain View, CA (US); David F. Chang, Los Altos, CA (US); Prashant Bhogilal Patel, San Jose, CA (US); Bengt Gunnar Brummer, San Francisco, CA (US); Jason Stanley Pi, Fremont, CA (US); Amy Lai Wong, Newark, CA (US)

(73) Assignee: Google LLC, Mountain View, CA (US)

(21) Appl. No.: 18/863,976

(22) PCT Filed: Apr. 28, 2023
(86) PCT No.: PCT/US2023/020369

§ 371 Date: Nov. 7, 2024

Related U.S. Application Data
(60) Provisional application No. 63/364,479, filed on May 10, 2022.

(51) Int. Cl. H01R 13/24; G06F 1/16

(52) U.S. Cl. CPC H01R 13/2421; G06F 1/1632

(57) ABSTRACT

In various embodiments, a spring-loaded pin includes an insulated body defining a housing having a first end and a second end. The spring-loaded pin includes a spring located within the housing having a first end and a second end abutted against the second end of the housing. The spring-loaded pin includes a ball supported by the first end of the spring and located within the housing. The spring-loaded pin includes a plunger having a first portion and a second portion. The second portion includes a bias cut surface with respect to a longitudinal axis defined by the housing. The second portion of the plunger abuts a portion of the ball opposite from the first end of the spring. A system comprises an array of spring-loaded pins that comprises at least two outer spring-loaded pins and at least two inner spring-loaded pins, the array providing lateral protection from short circuits.

### CROSS-REFERENCE TO RELATED APPLICATIONS

This PCT Patent Application claims the benefit of U.S. Provisional Patent Application No. 63/364,479, entitled “DOCKABLE AND UNDOCKABLE MULTI-PURPOSE ELECTRONIC TABLET DEVICE,” filed May 10, 2022, the entire disclosure of which is incorporated by reference herein for all purposes.

### BACKGROUND

Tablet computing devices, sometimes referred to as tablets or as tablet computers, are generally planar, lightweight devices that include a touch-screen display. Tablets are battery powered and can be plugged in to recharge the tablet's battery.

### SUMMARY

Embodiments described herein pertain to an electronic device having spring-loaded pins and arrangements thereof. In various embodiments, a spring-loaded pin includes an insulated body defining a housing. The housing includes a first end and a second end. The spring-loaded pin also includes a spring located within the housing. The spring has a first end and a second end abutted against the second end of the housing. The spring-loaded pin also includes a ball supported by the first end of the spring and located within the housing. The spring-loaded pin also includes a plunger having a first portion and a second portion. The second portion includes a bias cut surface with respect to a longitudinal axis defined by the housing. The second portion of the plunger abuts a portion of the ball opposite from the first end of the spring.

Embodiments of such an electronic device may comprise one or more of the following features: the spring applies force to the ball and the plunger such that the plunger protrudes from the housing and the plunger includes a flange portion, wherein the flange portion of the plunger forced by the spring abuts against a peripheral portion of the first end of the housing. In some embodiments, the ball includes copper and/or brass. In at least some embodiments, the ball has a diameter in a range of 1.05 mm to 1.15 mm. In some embodiments, the bias cut surface of the plunger is within a range of 12 degrees to 18 degrees. In at least some embodiments, the spring does not have a coating. The spring may have a diameter in a range of 1.07 mm to 1.17 mm. The housing may have a diameter in a range of 1.18 mm to 1.22 mm.

In various embodiments, a system includes and electronic device and a dock. The electronic device is removably coupled to the dock, the dock comprising an array of spring-loaded pins. Each spring-loaded pin includes an insulated body defining a cylindrical housing having a first end and a second end, a spring located within the housing, the spring having a first end and a second end abutted against the second end of the housing, a ball, the ball supported by the first end of the spring and located within the housing, and a plunger, the plunger having a first portion and a second portion including a bias cut surface with respect to a longitudinal axis defined by the housing. The second portion of the plunger abuts a portion of the ball opposite from the first end of the spring. The system further includes that the array comprises at least two outer spring-loaded pins and at least two inner spring-loaded pins, the array providing lateral protection from short circuits.

Embodiments of such an electronic device may comprise one or more of the following features: the at least two outer spring-loaded pins are associated with power and the at least two inner spring-loaded pins being associated with transferring data between the device and the dock. In other embodiments, the at least two outer spring-loaded pins are associated with transferring data between the device and the dock; and the at least two inner spring-loaded pins being associated with power. In some embodiments, the ball includes copper and/or brass. In at least some embodiments, the ball has a diameter in a range of 1.05 mm to 1.15 mm. In some embodiments, the bias cut surface of the plunger is within a range of 12 degrees to 18 degrees. In at least some embodiments, the spring does not have a coating. The spring may have a diameter in a range of 1.07 mm to 1.17 mm. The housing may have a diameter in a range of 1.18 mm to 1.22 mm. The system may further comprise a molding for facilitating alignment of the array of spring-loaded pins. In some embodiments, the system includes comprising an intermediate layer between the array of spring-loaded pins and the electronic device. In further embodiments, the system may comprise a plurality of contact pads located on the electronic device. In at least some embodiments, a number of contact pads is equal to a number of spring-loaded pins.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 illustrates an embodiment of a device that can be docked with a docking station or “dock” using magnets, according to some implementations of the present disclosure.

FIG. 2 illustrates a rear view of an embodiment of a device that is magnetically docked with a dock, according to some implementations of the present disclosure.

FIG. 3 illustrates a side view of an embodiment of a device that is magnetically docked with a dock, according to some implementations of the present disclosure.

FIG. 4A illustrates a spring-loaded pin, according to some implementations of the present disclosure.

FIG. 4B illustrates a cross-section of a spring-loaded pin, according to some implementations of the present disclosure.

FIG. 4C illustrates an exploded view of a spring-loaded pin, according to some implementations of the present disclosure.

FIG. 5A illustrates an embodiment of a device that can be docked with a docking station, according to some implementations of the present disclosure.

FIG. 5B illustrates an arrangement of spring-loaded pins, according to some implementations of the present disclosure.

FIG. 6A illustrates a cross-sectional side view of an electronic device having an arrangement of spring-loaded pins, according to some implementations of the present disclosure.

FIG. 6B illustrates a cross-sectional side view of an electronic device having an arrangement of spring-loaded pins, according to some implementations of the present disclosure.

FIG. 7 illustrates a flowchart of a method of manufacture of spring-loaded pins, according to some implementation of the present disclosure.

FIG. 8 illustrates a spring-loaded pin, according to some implementations of the present disclosure.

FIG. 9 illustrates a block diagram of an embodiment of a tablet dock system.

### DETAILED DESCRIPTION

Various embodiments are described related to spring loaded pins and how such pins can be used with an electronic device, such as a tablet computer and a dock for the tablet computer. The electronic device may comprise one or more of electrical contacts that are used to transfer electrical signals between the dock and the electronic device when the electronic device is docked, such as magnetically, with the dock. The dock can include spring-loaded pin connectors (e.g., spring-loaded pins) for electrically connecting with the electrical contacts and transferring electrical signals between the dock and the electronic device. In various embodiments, the spring-loaded pins include a housing, a spring, a ball, and a plunger. The plunger can include a bias cut surface with respect to a longitudinal axis defined by the housing.

Spring-loaded pins may include a plunger assembly having a bias where a bias cut surface allows for variation in the z-height (e.g., a vertical height of the pins) as the bias cut slides against a spring and is suitable for general static contact applications. For example, the biased tail of the plunger creates a lateral force and better contact with the spring. However, bias angles can make the spring-loaded pins unstable during applications involving vibration, such as when audio is output by a speaker of the device in which the spring-loaded pins are located or in contact. For example, the spring contacts the housing, electrical current flows through the spring, and shorts the circuit resulting in failure of the spring-loaded pin, such as by the spring-loaded pin burning, yielding, freezing, or collapsing over time. Accordingly, there is a need in the art for spring-loaded pins having improved contact stability and which are suitable for both static and vibration applications. Various embodiments of the present disclosure optimize the size of the ball, especially with respect to the size of the housing as a ratio, to increase stability of the spring-loaded pins during vibration applications.

Spring-loaded pins may be a component in coupling and aligning a tablet computer to a dock. Spring-loaded pins may be used to allow for electrical signals, which can include data, power, or both, to be exchanged between the tablet computer and the dock. In some designs, misalignment of the tablet computer and the charging dock may result in catastrophic consequences, e.g., shorting the circuit between the tablet computer and the dock, and burning out the components thereof. Accordingly, there is a need in the art for an arrangement of spring-loaded pins which enables consumer usability and additional protection from unintentional alignment resulting in shorting of the spring-loaded pins.

The embodiments detailed herein are focused on spring-loaded pins. In some embodiments, the spring-loaded pins are installed on a dock for electronic device is a tablet computer that is a component of a tablet computer system. Specifically, a tablet computer can serve as a home assistant device and/or hub to manage smart home devices in an environment. The tablet computer may be able to record video, communicate with a remote server system, and interact with users via spoken communications. For example, a home assistant device may provide automated control or voice control of devices, appliances, and systems, such as heating, ventilation, and air conditioning (“HVAC”) system, lighting systems, home theater, entertainment systems, as well as security systems. Smart home networks may include control panels that a person may use to input settings, preferences, and scheduling information that the smart home network uses to provide automated control of the various devices, appliances, and systems in the home. For example, the person may input a schedule indicating when the person is away from the home, and the smart home network uses this information along with information obtained from various devices in the home to detect unauthorized entry when the user is away. The tablet computer may be left docked with a dock to charge its battery and use other features of the dock, such as one or more integrated speakers. The tablet computer may be removed from the dock for convenience to be used or displayed at another location. When not in use (whether docked, not docked, or both), photos or photo albums selected by a user may be presented by the tablet.

Many other types of electronic devices can benefit from spring-loaded pins suitable for vibration applications within an electronic device. For example, smartphones, gaming devices, e-readers, personal digital assistants (PDAs), digital paper tablets, docks for various types of electronic devices, and smart picture frames may benefit from various embodiments of spring-loaded pins as detailed herein. Furthermore, the electronic device may be an assistant device (e.g., Google® Nest® Hub; Google® Nest® Hub Max); a home automation controller (e.g., controller for an alarm system, thermostat, lighting system, door lock, motorized doors, etc.); a gaming device (e.g., a gaming system, gaming controller, data glove, etc.); a communication device (e.g., a smart phone such as a Google® Pixel® Phone, cellular phone, mobile phone, wireless phone, portable phone, radio telephone, etc.); and/or other computing device (e.g., a tablet computer, phablet computer, notebook computer, laptop computer, etc.).

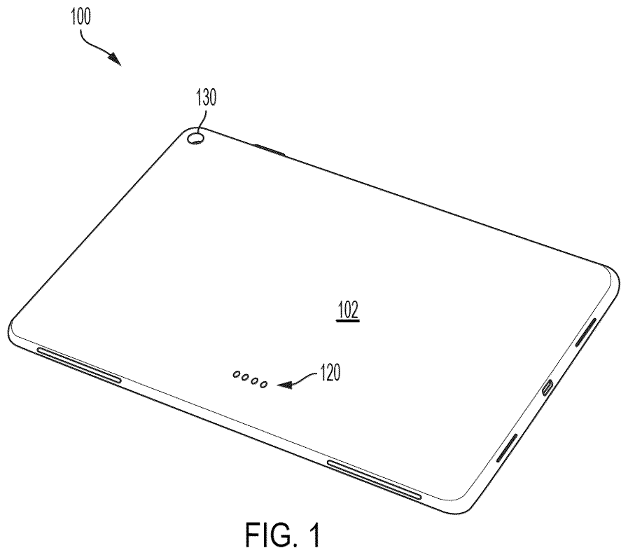

Further detail is provided in reference to the figures. FIG. 1 illustrates an embodiment of an electronic device 100 that is configured to dock with a dock using magnets and contact pads 120 which contact spring-loaded pins. The electronic device 100 can be a tablet computer or, more specifically, a tablet computer that serves as a home assistant device or hub as previously detailed. One or more magnets may be hidden within the electronic device 100 behind rear surface 102. Device 100 can include one or more conductive contact pads 120 (e.g., metallic pads) that are used to transfer data with and/or obtain power from a dock when the device 100 is in a docked position. As illustrated, four contact pads 120 are present. In other embodiments, a greater or fewer number of contact pads 120 may be present. The arrangement of contact pads 120 can also vary by embodiment. In other embodiments, rather than using contact pads, some other form of electrical contact may be used, such as spring-loaded pins, as detailed herein, or a combination of pads and pins. Other components, such as camera 130, may be present on or accessible through rear surface 102.

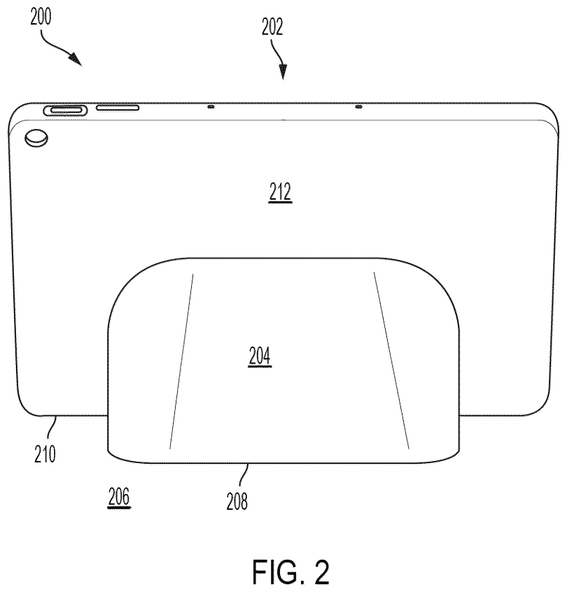

FIG. 2 illustrates a rear view of an embodiment of a system 200 that includes an electronic device 202 docked with a dock 204. The dock 204 connects with the electronic device 202 via one or more magnets of dock 204 that magnetically attract to corresponding magnets of the electronic device 202. When coupled, the electronic device 202 can be suspended off of surface 206, upon which a base 208 of the dock 204 rests. Accordingly, edge 210 may not touch surface 206 when the electronic device 202 is docked with the dock 204.

The dock 204 magnetically couples with the electronic device 202 on rear surface 212. Since the connection is magnetic, a user may pull the electronic device 202 away from the dock 204 to remove. To mate, the user may move the electronic device 202 close to the dock 204. Once close, the magnets of the electronic device 202 and magnets of the dock 204 help guide the electronic device 202 into the proper alignment on the dock 204. When docked, contact pads (such as contact pads 120 in FIG. 1) make contact with corresponding spring-loaded pins, such as those embodiments of spring-loaded pins detailed herein, or another form of electrical contact present on the mating surface of the dock 204.

In some embodiments, one or more electromagnets may be present within the dock 204 that can be engaged or disengaged. When activated, such magnets may prevent the electronic device 202 from being easily removed by a user from the dock 204. When deactivated or the polarity is reversed, it may be relatively easy (compared to when activated) for the user to the electronic device 202 from the dock 204.

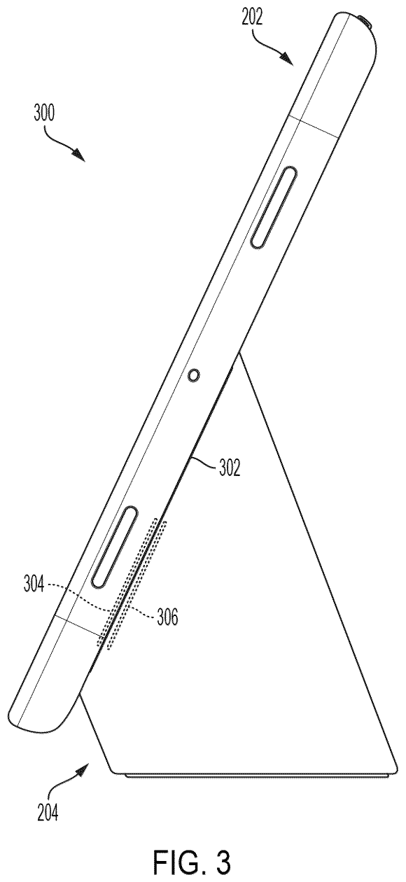

FIG. 3 illustrates a side view of a system 300 that includes an embodiment of an electronic device attached with a dock. As can be seen from the side view, the electronic device 202 is docked with dock 204. Mating surface 302 indicates where the rear surface 212 of the electronic device 202 contacts the dock 204.

Within region 304, a first plurality of magnets is present within the electronic device 202. In corresponding locations within region 306, a second plurality of magnets is present within the dock 204. The magnets are arranged such that, when brought into proximity, the magnets of the electronic device 202 attract to the magnets of the dock 204 to help correctly position and align the dock 204 against the electronic device 202 and hold the electronic device 202 in a correct position on the dock 204. In other embodiments, regions 304 and 306 may extend further upward on the dock 204 and/or extend the length of the dock 204 which contacts the electronic device 202. For example, regions 304 and 306 may be any size and located at any location on the electronic device 202 and/or the dock 204.

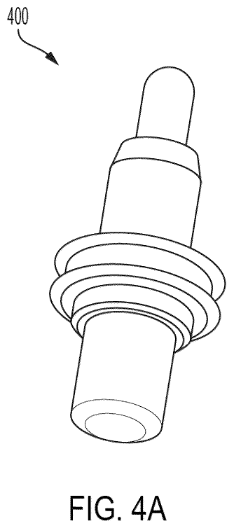

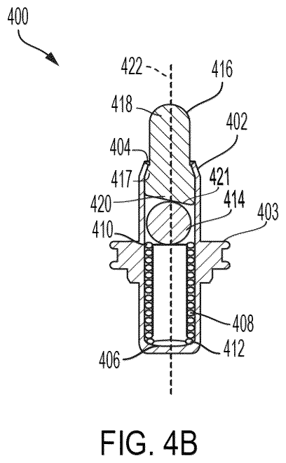

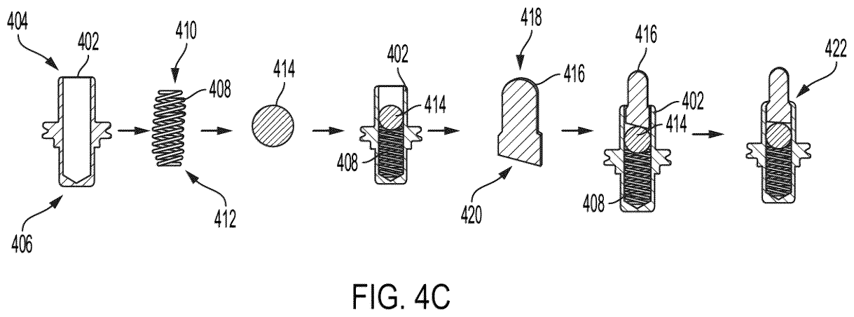

As previously detailed, to make electrical connections for data and/or power between an electronic device and another device, such as a dock, conductive pads may be used in combination with spring-loaded pins. Referring now to FIG. 4A, a spring-loaded pin 400 is shown. FIG. 4B illustrates a cross-section of a spring-loaded pin 400 in accordance with various embodiments described herein. As shown, the spring-loaded pin 400 includes an insulated body defining a cylindrical housing 402. The housing 402 includes a first end 404 and a second end 406. In some embodiments, the housing 402 is cylindrical. In other approaches, and as shown in FIG. 4A, the housing 402 includes an exterior barrel portion 403 for gripping and/or placement in an electronic device (e.g., such as electronic device 202). In various embodiments, the housing 402 includes brass. In at least some embodiments, a plating on the housing 402 (not shown) includes nickel, gold, palladium, etc., or any combination thereof. For example, in some embodiments, the housing 402 includes C3604 brass which is a type of brass that includes a mixture of copper, zinc, and other elements. In various embodiments, the housing 402 includes copper. In further embodiments, the housing 402 includes a low conductivity copper having 25% conductivity for providing insulation which can prevent the spring-loaded pin 400 from burning out. In various embodiments, the housing 402 has an inner diameter in a range of 1.18 mm to 1.22 mm. In at least some embodiments, the housing 402 inner diameter is 1.2 mm. In various embodiments, the housing 402 has an outer diameter in a range of 1.58 mm to 1.62 mm. In at least some embodiments, the outer diameter of the housing 402 is 1.6 mm.

The spring-loaded pin 400 includes a spring 408 located within the housing 402. The spring 408 includes a first end 410 and a second end 412 abutted against the second end 406 of the housing 402. In various embodiments, the spring 408 includes stainless steel. For example, in some embodiments, the spring 408 includes stainless steel SUS301. The spring 408 does not include plating in some embodiments. In various embodiments, the spring 408 has a diameter in a range of 1.07 mm to 1.17 mm. In at least some embodiments, the diameter of the spring 408 is 1.12 mm. The diameter of the wire of the spring 408 may be in the range of 0.12 mm±0.008 mm, in various embodiments.

In various embodiments, the spring 408 does not include a coating, such as a parylene insulation coating. The lack of coating in the spring described throughout the present disclosure can increase the working range of the spring and spring-loaded pin systems described herein. In particular, spring-loaded pins having springs with a coating may have limited manufacturing temperatures. For example, coatings such as parylene insulation coatings tend to melt at high temperatures and are therefore unsuitable for surface mount technology (SMT) processes.

Accordingly, spring-loaded pins having springs with coatings can be formed using high touch-time techniques such as spot-welding. Such techniques may increase the cost and decrease the manufacturability of spring-loaded pins. In stark contrast, at least some embodiments of spring 408 do not include a coating, is characterized by having a higher heat resistance, and is suitable for SMT processes. Such arrangements can result in cost reductions and an increase in the efficiency of manufacturing.

The spring-loaded pin 400 further includes a ball 414. The ball 414 is supported by the first end 410 of the spring 408 and located within the housing 402. In various embodiments, the ball 414 includes copper. In some embodiments, the ball 414 further includes nickel, gold, or both. In particular, the ball 414 may include a copper alloy having a nickel and gold plating. For example, the ball 414 may include a nickel and gold plating which is 1.0 μm thick. In various embodiments, the ball 414 has a diameter in a range of 1.05 mm to 1.15 mm. The diameter of the ball 414 may include the plating, in some embodiments.

The diameter of the ball 414 with respect to the diameter of the housing 402 described herein increases the conductive pathway of current flowing through the spring-loaded pin 400. For example, optimizing the diameter of the ball and the diameter of the housing increases the ball interface with the housing to produce consistent current flow through the ball, rather than the spring. The ratio of the diameters provides more frequent and more reliable current flow through the ball, rather than through the spring which results in burning out components of the spring-loaded pins in some designs. In various aspects, a ratio of a diameter of the ball to a diameter of the housing (e.g., the inner diameter of the housing) is between 0.89 to 0.95. The foregoing range of ratios between the diameter of the ball to the diameter of the housing provides increased stability of the spring-loaded pins used in acoustic (e.g., high vibration) applications, such as those present in a dockable and undockable tablet computer system described herein. Accordingly, the ball is more stable within the housing and is less receptive to shaking and shorting induced by vibration applications. Optimization of the diameter of the ball and the diameter of the housing was achieved for high vibration tablet computer applications such as docking and undocking of the tablet from the dock.

The spring-loaded pin 400 further includes a plunger 416 having a first portion 418 and a second portion 420. In some embodiments, the second portion 420 includes a bias cut surface with respect to a longitudinal axis 422 defined by the housing 402. In various embodiments, the bias cut surface 421 is offset from the longitudinal axis 422 in a range of 12 degrees to 18 degrees, inclusive. In some embodiments, the bias cut surface 421 is offset from the longitudinal axis 422 by 15 degrees. In various embodiments, the second portion 420 of the plunger 416 abuts a portion of the ball 414 opposite from the first end 410 of the spring 408. In at least some approaches, a plating on the plunger 416 (not shown) includes nickel, gold, palladium, etc., or any combination thereof. For example, in some embodiments, the plunger 416 includes C3604 brass which is a type of brass that includes a mixture of copper, zinc, and other elements. In various embodiments, the plunger 416 includes copper. In further embodiments, the plunger 416 includes a low conductivity copper having 25% conductivity for providing additional insulation and preventing burn out of the spring-loaded pin 400. For example, the plunger 416 and the housing 402 may include the same materials, in some embodiments. In other embodiments the plunger 416 and the housing 402 include different materials.

In various embodiments, the spring 408 applies a force to the ball 414 and the plunger 416, described in further detail below, such that the plunger 416 protrudes from the housing 402. For example, the first portion 418 of the plunger 416 may be located outside the housing 402 and the second portion 420 of the plunger 416 may be located within the housing 402. In some embodiments, the plunger 416 includes a flange portion 417 surrounding substantially all of the plunger 416. In other embodiments, the plunger 416 includes a plurality of flange portions 417 spaced around the plunger 416. The flange portion 417 of the plunger 416 may be forced upwards (e.g., out of the housing 402) by the spring 408 which abuts against a peripheral portion of the first end 404 of the housing 402. The peripheral portion of the first end 404 of the housing 402 may be “necked” to maintain the flange portion 417 of the plunger 416 within the housing 402.

FIG. 4C illustrates an expanded view of cross-sections of the components of the spring-loaded pin 400 described in detail with respect to FIG. 4A. FIG. 4C illustrates one aspect of assembly of the spring-loaded pin 400 including inserting the spring 408 (not shown in cross-section form for simplicity) and ball 414 in the housing 402 with the ball 414 supported by the first end 410 of the spring 408. The plunger 416 is inserted such that the second portion 420 of the plunger 416 comprising the bias cut surface 421 interfaces with the ball 414 and the first portion 418 of the plunger 416 extends out of the first end 404 of the housing 402. The peripheral portion of the first end 404 of the housing 402 is shown as being necked around the first portion 418 of the plunger to maintain the plunger 416 at least partially within the housing 402.

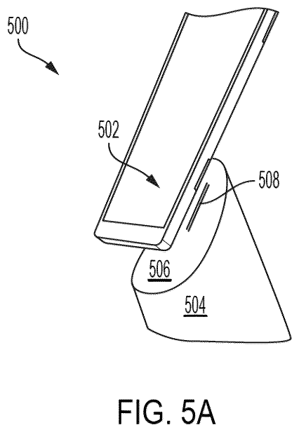

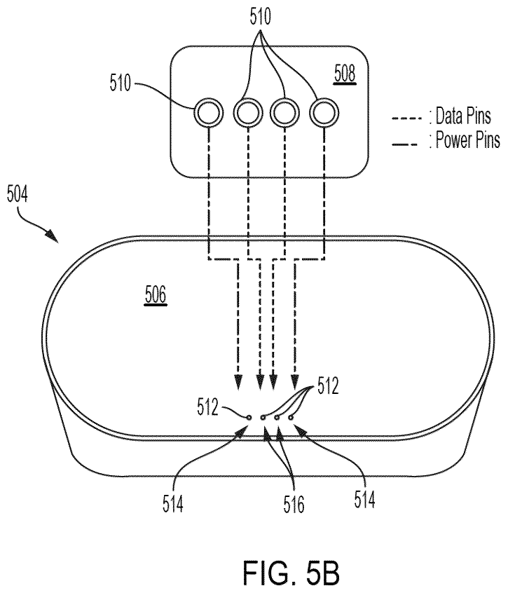

Referring now to FIG. 5A, a system 500 includes an electronic device 502 and a dock 504 where the electronic device 502 is removably coupled to the dock 504. The dock 504 includes an array of spring-loaded pins (such as spring-loaded pins 400 described with respect to FIGS. 4A-4C, not shown) and the electronic device 502 includes an array of electrical contact pads (such as contact pads 120 described with respect to FIG. 1, not shown). A face 506 (or a portion of the face 506) of the dock 504 interfaces with a portion 508 of the electronic device 502. The portion 508 of the electronic device 502 may include as much as the entire back surface of the electronic device 502, in some embodiments.

As shown in FIG. 5B illustrates a view of a portion 508 of the electronic device 502 which interfaces with the face 506 of the dock 504. The portion 508 of the electronic device 502 includes contact pads 510. Contact pads 510 may include multiple conductive contact pads, such as contact pads 120 (e.g., metallic pads) described with respect to FIG. 1, that are used to transfer data with and/or obtain power from the dock 504 when the electronic device 502 is in a docked position. In various embodiments, the number of contact pads 510 is the same as the number of spring-loaded pins 512 located within the face 506 of the dock 504. In various embodiments, the portion 508 of the electronic device 502 includes at least four contact pads 510 and the face 506 of the dock 504 includes at least four spring-loaded pins 512, although any number of contact pads 510 and spring-loaded pins 512 may be used.

In some embodiments, an array of the spring-loaded pins 512 include at least two outer spring-loaded pins 514 and at least two inner spring-loaded pins 516 when the spring-loaded pins 512 are arranged in a substantially horizontal line. In other embodiments, the spring-loaded pins 512 may be arranged in a substantially vertical line or in any other physical arrangement on face 506. In some embodiments, the at least two outer spring-loaded pins 514 are associated with transferring data between the electronic device 502 and the dock 504 and the at least two inner spring-loaded pins 516 are associated with power (e.g., transferring power between the electronic device 502 and the dock 504). In other embodiments, the at least two inner spring-loaded pins 516 are associated with transferring data between the electronic device 502 and the dock 504 and the at least two outer spring-loaded pins 514 are associated with power (e.g., transferring power between the electronic device 502 and the dock 504). In various embodiments, the array of spring-loaded pins 512 including at least two outer spring-loaded pins 514 and at least two inner spring-loaded pins 516 provides lateral protection from short circuits. For example, the particular arrangement of spring-loaded pins 512 described herein helps prevent misalignment of the spring-loaded pins 512 and the contact pads 510 which result in burned out components and/or component failure. Alternating power and data connectors can increase the likelihood of misalignment resulting in short circuits. As such, arrangements detailed herein can result in fewer such circuits or other forms of failures.

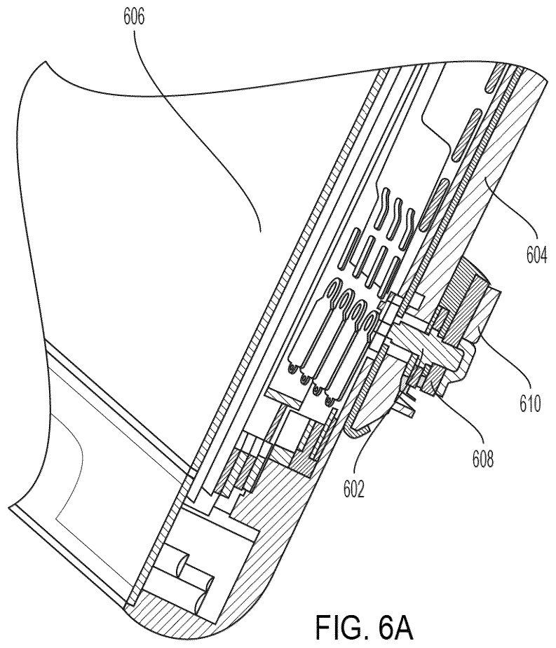

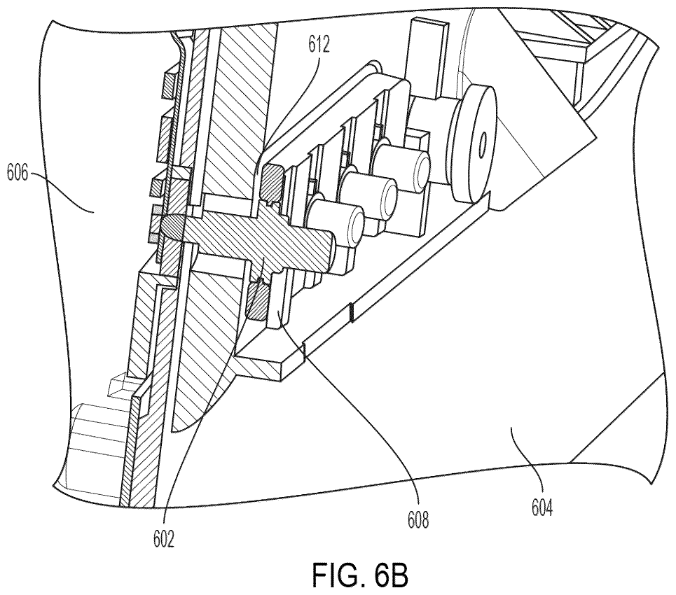

FIG. 6A depicts a cross-section of a spring-loaded pin 602 located within a dock 604 and interfacing an electronic device 606. Spring-loaded pin 602 can represent an embodiment of the spring-loaded pins detailed in relation to any other figure, including FIGS. 4A-4C. In various embodiments, an array of spring-loaded pins 602 are installed onto a molding 608 which facilitates alignment (e.g., straightness and spacing) within the dock 504 and between the electronic device 606. A cap 610 may further facilitate the alignment process. In some embodiments, the cap 610 is removed once the spring-loaded pins 602 and the molding 608 are installed onto the dock 604. The molding 608 and the cap 610 may include one or more high temperature resistant materials which are configured for use in a surface mount technology (SMT) process, as described in further detail below.

FIG. 6B illustrates a close-up of the cross-sectional side view of FIG. 6A with the cap 610 removed. An intermediate layer 612 is shown between the spring-loaded pin 602 and the electronic device 606. The intermediate layer 612 may be a foam material. In some embodiments, the intermediate layer 612 is waterproof. In various embodiments, the intermediate layer 612 prevents solder from touching other components of the system and/or protects the spring-loaded pin 602 from vibrations produced by other components within the dock 604 (such as a speaker, not shown).

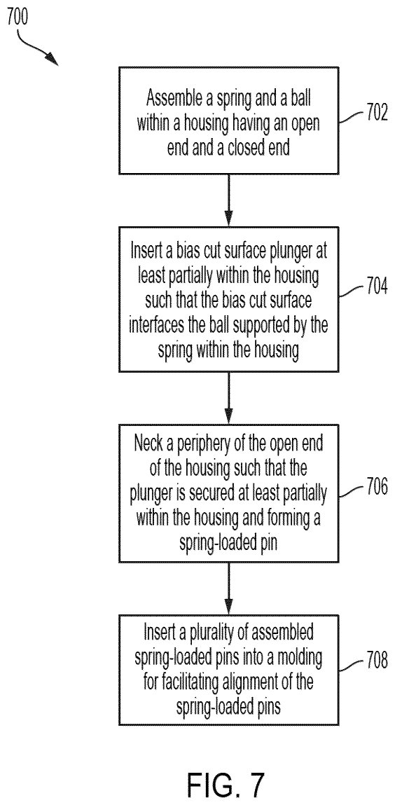

FIG. 7 is a flowchart of a method 700 of manufacture, in accordance with various embodiments of the present disclosure. Step 702 includes assembling a spring and a ball within a housing having an open end and a closed end. The spring, the ball, and the housing may be of the type described in detail with respect to FIGS. 4A-4C and may be arranged according to any of the embodiments described herein.

Step 704 includes inserting a bias cut surface plunger at least partially within the housing such that the bias cut surface interfaces the ball supported by the spring within the housing. The plunger may similarly be of the type described in detail with respect to FIGS. 4A-4C and may be arranged according to any of the embodiments described herein.

Step 706 includes necking a periphery of the open end of the housing such that the plunger is secured at least partially within the housing and forming a spring-loaded pin. For example, the plunger may comprise a flange portion which, combined with the necking of the housing, secures the spring-loaded pin components within the housing. In some embodiments, the spring-loaded pins are tested and inspected for spring force and resistance prior to proceeding to the next step in a manner known in the art.

Step 708 includes inserting a plurality of assembled spring-loaded pins into a molding for facilitating alignment (e.g., straightness and spacing) of the spring-loaded pins. Step 708 may include checking the resistance and/or the force of the spring-loaded pins according to various quality requirements determined by a person having ordinary skill in the art in view of the intended application. For example, spring-loaded pins as described herein may have relatively higher standards for resistance and force capabilities where the spring-loaded pins are used in high-vibration, acoustic applications. Step 708 may also include installing a cap. A cap further facilitates alignment during an SMT process and provides a pick-up area for the SMT machinery. The cap may be removed after the SMT process, in at least some embodiments. In some embodiments, tape reel packing is used to manufacture and distribute the assembled spring-loaded pins.

In various embodiments, the spring-loaded pins described throughout the present disclosure are manufactured using a SMT process. The SMT process applies electronic components directly onto the surface of a printed circuit board (PCB). This process allows for automated production to complete more of the assembly process, thereby reducing high-cost touch-time manufacturing steps. For example, the molding and/or the cap may be used to secure the spring-loaded pin in position when moved by machinery during production. As described above, spring-loaded pins having a coating or comprising less heat resistant materials are unsuitable for SMT processes which operate at relatively high temperatures (e.g., compared to spot welding techniques used to manufacture various spring-loaded pin designs).

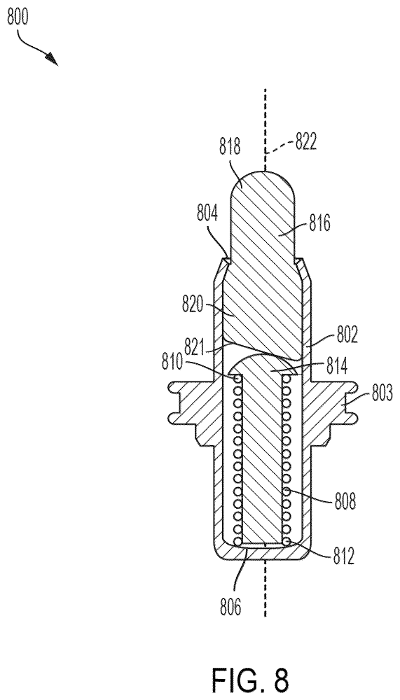

Referring now to FIG. 8, a cross-section of a dual-plunger spring-loaded pin 800 is illustrated in accordance with various embodiments described herein. As shown, the dual-plunger spring-loaded pin 800 includes an insulated body defining a cylindrical housing 802, similar to cylindrical housing 402 described in detail above. The housing 802 includes a first end 804 and a second end 806. In some approaches, the housing 802 is cylindrical. In other approaches, and as shown in FIG. 8, the housing 802 includes an exterior barrel portion 803 for gripping and/or placement in an electronic device (e.g., such as electronic device 202). In various embodiments, the housing 802 includes brass. In at least some approaches, a plating on the housing 802 (not shown) includes nickel, gold, palladium, etc., or any combination thereof. For example, in some embodiments, the housing 802 includes C3604 brass which is a type of brass that includes a mixture of copper, zinc, and other elements. In various embodiments, the housing 802 includes copper. In further embodiments, the housing 802 includes a low conductivity copper having 25% conductivity for providing insulation which can prevent the spring-loaded pin 800 from burning out. In various embodiments, the housing 802 has an inner diameter in a range of 1.18 mm to 1.22 mm. In at least some embodiments, the inner diameter of the housing 802 is 1.2 mm. In various embodiments, the housing 802 has an outer diameter in a range of 1.58 mm to 1.62 mm. In at least some embodiments, the outer diameter of the housing 802 is 1.6 mm.

The dual-plunger spring-loaded pin 800 includes a spring 808 located within the housing 802. The spring 808 includes a first end 810 and a second end 812 abutted against the second end 806 of the housing 802. In various embodiments, the spring 808 includes stainless steel. For example, in some embodiments, the spring 808 includes stainless steel SUS301. The spring 808 does not include plating in some embodiments. In various embodiments, the spring 808 has a diameter in a range of 1.07 mm to 1.17 mm. In at least some embodiments, the diameter of the spring 408 is a 1.12 mm. The diameter of the wire of the spring 808 may be in the range of 0.12 mm±0.008 mm, in various embodiments.

In various embodiments, the spring 808 does not include a coating, such as a parylene insulation coating. The lack of coating in the spring described throughout the present disclosure increases the working range of the spring and spring-loaded pin systems described herein. In particular, spring-loaded pins having springs with a coating have limited manufacturing temperatures. For example, coatings such as parylene insulation coatings tend to melt at high temperatures and are therefore unsuitable for surface mount technology (SMT) processes. Accordingly, spring-loaded pins having springs with coatings are formed using high touch-time techniques such as spot-welding. Such techniques increase the cost and decrease the manufacturability of spring-loaded pins. In stark contrast, spring 808 does not include a coating, is characterized by having a higher heat resistance, and is suitable for SMT processes, thereby reducing costs and increasing the efficiency of manufacturing.

The spring-loaded pin 800 further includes a first plunger 816 having a first portion 818 and a second portion 820. In some embodiments, the second portion 820 includes a bias cut surface 821 with respect to a longitudinal axis 822 defined by the housing 802. In various embodiments, the bias cut surface 821 is offset from the longitudinal axis 822 in a range of 12 degrees to 18 degrees. In some embodiments, the bias cut surface 821 is offset from the longitudinal axis 822 by 15 degrees. In various embodiments, the second portion 820 of the first plunger 816 abuts a portion of the second plunger 814 opposite from the first end 810 of the spring 808. In at least some approaches, a plating on the first plunger 816 (not shown) includes nickel, gold, palladium, etc., or any combination thereof. For example, in some embodiments, the first plunger 816 includes C3604 brass which is a type of brass that includes a mixture of copper, zinc, and other elements. In various embodiments, the first plunger 816 includes copper. In further embodiments, the first plunger 816 includes a low conductivity copper having 25% conductivity. For example, the first plunger 816 and the housing 802 may include the same materials, in some embodiments. In other embodiments the first plunger 816 and the housing 802 include different materials.

The dual-plunger spring-loaded pin 800 further includes a second plunger 814. The second plunger 814 is supported by the first end 810 of the spring 808 and located within the housing 802. In various embodiments, the second plunger 814 includes copper. In some embodiments, the second plunger 814 further includes nickel, gold, or both. In particular, the second plunger 814 may include a copper alloy having a nickel and gold plating. For example, the second plunger 814 may include a nickel and gold coating which is 1.0 μm thick.

In embodiments having a dual-plunger spring-loaded pin, such as dual-plunger spring-loaded pin 800, advantageously requires less compression of the spring, thereby providing more stability and increased reliability in the current flow through the second plunger (e.g., a cap), rather than through the spring. The rounded first portion of the second plunger further provides a more even surface for providing compression forces from the first plunger, through the second plunger, and into the spring. The second plunger also enables flexibility in the z-height of the spring-loaded pin along the longitudinal axis where the rounded portion of the second plunger abuts the top of the spring rather than adding additional height to the overall height of the spring-loaded pin.

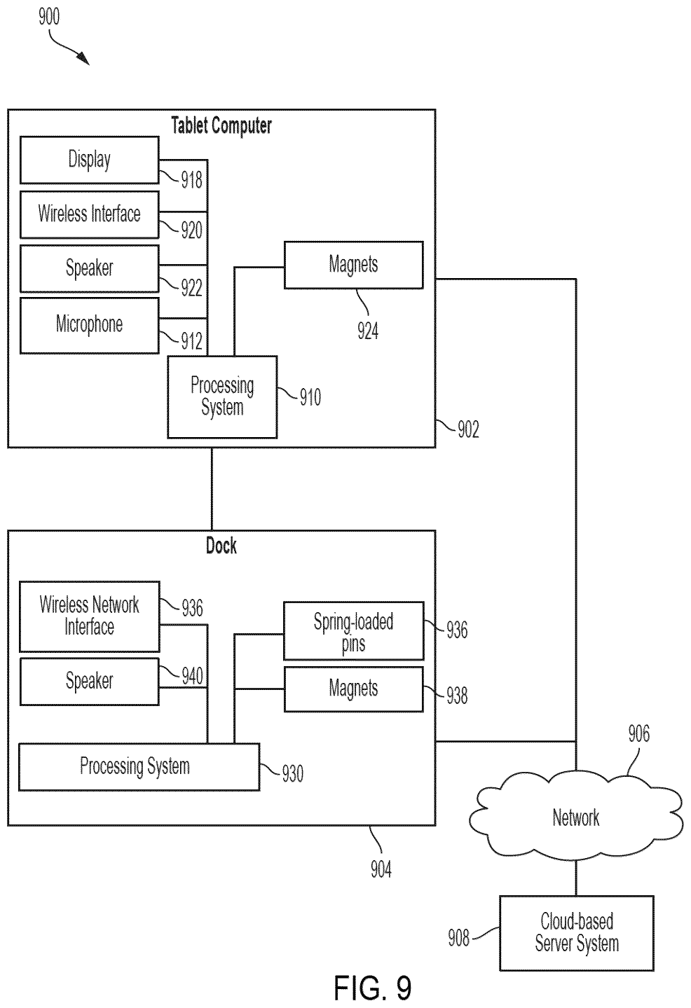

FIG. 9 illustrates an embodiment of a tablet dock system 900. System 900 can include tablet computer 902, a dock 904, a network 906; and cloud-based server system 908. The tablet computer 902 can include: processing system 910; one or more microphones 912; an electronic display 918; and a wireless interface 920. Processing system 910 may include one or more processors, which can include special-purpose or general-purpose processors that execute instructions stored using one or more non-transitory processor readable mediums. Processing system 910 can include one or more processors that are designed to execute machine learning (ML) models. Such processors, while able to analyze whether speech is or is not present, may not be able to analyze the content of such speech. Therefore, privacy of the content of the speech is maintained. Syntiant® Neural Decision Processors™ represent one family of commercial processors that can execute a machine learning model that is trained to determine the presence of speech but otherwise ignore the content of such speech.

Microphones 912 are configured to receive audio input from a user of the tablet computer 902. One or more microphones 912 may be in communication with processing system 910. If multiple microphones 912 are present, based upon the difference in time of arrival of sound at the multiple microphones, a direction from which a sound, such as speech, originated may be determined in relation to a SIM device. One or more microphones 912 may be in direct communication with only processing system 910 via a direct connection. Specifically, one or more microphones 912 can be electrically connected to only a processor that executes a machine learning model that determines (e.g., a binary determination of whether or not speech is determined to be present) or scores (e.g., indicates a likelihood of speech being present) if speech is or is not present. The processor does not have the capability to analyze the content of the speech. In various embodiments, the tablet computer 902 may include a speaker 922 of a type known in the art to output audio feedback to commands.

Magnets 924 may include one or more magnets arranged to magnetically couple with corresponding one or more magnets 938 of the dock. Magnets 924 and magnets 938 may be used to align the tablet computer 902 with the dock 904 during docking. Magnets 924 (or magnets 938) may include EPMs or permanent magnets, or a combination thereof.

Wireless interface 920 is in communication with processing system 910 and allows for communication with various wireless networks and/or wireless devices using one or more communication protocols. Wireless interface 920 may allow for communication with a Wi-Fi based wireless local area network. Wireless interface 920 can allow for communication directly with other devices, such as via Bluetooth, Bluetooth Low Energy (BLE), or some other low-power device-to-device communication protocol. In some embodiments, wireless interface 920 allows for communication with a wearer's smartphone, thus allowing information collected using the tablet computer 902 to be analyzed by and presented using the wearer's smartphone.

In some embodiments, electronic display 918 may be present. In various embodiments, the electronic display 918 may display any visual information associated with any applications running on the tablet computer 902 known in the art. Electronic display 918 can allow for information determined based on data collected from the various sensors of the tablet computer 902 to be directly presented to a user. For example, the electronic display 918 may display information or commands associated with smart home devices, social media applications, internet searches, weather applications, news applications, etc. For instance, electronic display 918 may be able to present text and/or graphical indications of whether the wearer's social interactions are above, at, or below a goal for a specific time period, such as a day.

The tablet computer 902 may be or may be used with a smartphone, a smartwatch, laptop, gaming device, or a smart home hub device that is used to interact with various smart home devices present within a home. The dock 904 may generally be part of a smart home assistant device system. Generally, the dock 904 can include a housing that houses all of the components of the dock 904.

The dock 904 can include a processing system 930. Processing system 930 can include one or more processors configured to perform various functions. Processing system 930 can include one or more special-purpose or general-purpose processors. Such special-purpose processors may include processors that are specifically designed to perform the functions detailed herein. Such special-purpose processors may be ASICs or FPGAs which are general-purpose components that are physically and electrically configured to perform the functions detailed herein. Such general-purpose processors may execute special-purpose software that is stored using one or more non-transitory processor-readable mediums, such as random access memory (RAM), flash memory, a hard disk drive (HDD), or a solid state drive (SSD).

Dock 904 may include a spring-loaded pin 936 or an arrangement of spring-loaded pins 936 located on the face of the dock 904 such as those described throughout the present disclosure. The dock 904 may include a speaker 940 (similar to speaker 922) of a type known in the art to output audio feedback to commands.

In various embodiments, other sensors or components (not shown) may be located on the dock 904. For example, one or more environmental sensors may be incorporated into the dock 904 and can include a light sensor, a microphone for receiving audio input from a user, a temperature sensor, etc. In some embodiments, multiple instances of some or all of these sensors may be present. A camera and/or humidity sensor may be incorporated into the dock 904 and/or the tablet computer 902. As another example, active infrared sensors may be included. In some embodiments, some data, such as humidity data, may be obtained from a nearby weather station that has data available via the Internet. In some embodiments, active acoustic sensing methods, including, but not limited to, sonar and ultrasound, and including either single or arrayed acoustic sources and/or receivers may be implemented. Such arrangements may be used as one or more adjunct sensing modalities incorporated with the other sensors and methods described herein.

Tablet computer 902 may include various interfaces. Display 918, which may be a touchscreen, can allow processing system 910 to present information for viewing by one or more users. A wireless network interface can allow for communication using a wireless local area network (WLAN), such as a WiFi-based network. Speaker 922 can allow for sound, such as synthesized speech, to be output. For instance, responses to spoken commands received via microphone 912 may be output via speaker 922 and/or display 918. The spoken commands may be analyzed locally by the tablet computer 902 or may be transmitted via a wireless network interface to cloud-based server system 908 for analysis. A response, based on the analysis of the spoken command, can be sent back to the tablet computer via the wireless network interface for output via speaker 922 and/or display 918. Additionally, or alternatively, the speaker 922 and microphone 912 may be collectively configured for active acoustic sensing, including ultrasonic acoustic sensing. Additionally, or alternatively, other forms of wireless communication may be possible, such as using a low-power wireless mesh network radio and protocol (e.g., Thread) to communicate with various smart home devices. In some embodiments, a wired network interface, such as an Ethernet connection, may be used for communication with a network. Further, the evolution of wireless communication to fifth generation (5G) and sixth generation (6G) standards and technologies provides greater throughput with lower latency which enhances mobile broadband services. 5G and 6G technologies also provide new classes of services, over control and data channels, for vehicular networking (V2X), fixed wireless broadband, and the Internet of Things (IoT). Such standards and technologies may be used for communication by the tablet computer 902.

The low-power wireless mesh network radio and protocol may be used for communicating with power limited devices. A power-limited device may be an exclusively battery powered device. Such devices may rely exclusively on one or more batteries for power and therefore, the amount of power used for communications may be kept low in order to decrease the frequency at which the one or more batteries need to be replaced. In some embodiments, a power-limited device may have the ability to communicate via a relatively high power network (e.g., WiFi) and the low-power mesh network. The power-limited device may infrequently use the relatively high power network to conserve power. Examples of such power-limited devices include environmental sensors (e.g., temperature sensors, carbon monoxide sensors, smoke sensors, motion sensors, presence detectors) and other forms of remote sensors.

Notably, some embodiments of the tablet computer 902 do not have any still camera or video camera. By not incorporating an on-board camera, users nearby may be reassured about their privacy. For example, the tablet computer 902 can typically be installed in a user's bedroom. For many reasons, a user would not want a camera located in such a private space or aimed toward the user while the user is sleeping. In other embodiments, the tablet computer 902 may have a camera, but the camera's lens may be obscured by a mechanical lens shutter. In order to use the camera, the user may be required to physically open the shutter to allow the camera to have a view of the environment of the tablet computer 902. The user can be assured of privacy from the camera when the shutter is closed.

Wireless network interface can allow for wireless communication with network 906. Network 906 can include one or more public and/or private networks. Network 906 can include a local wired or wireless network that is private, such as a home wireless LAN. Network 906 may also include a public network, such as the Internet. Network 906 can allow for the tablet computer 902 to communicate with remotely located cloud-based server system 908.

Cloud-based server system 908 may additionally or alternatively provide other cloud-based services. For instance, the tablet computer 902 may additionally function as a home assistant device. A home assistant device may respond to vocal queries from a user. In response to detecting a vocal trigger phrase being spoken, the tablet computer 902 may record audio. A stream of the audio may be transmitted to cloud-based server system 908 for analysis. Cloud-based server system 908 may perform a speech recognition process, use a natural language processing engine to understand the query from the user, and provide a response to be output by the tablet computer 902 as synthesized speech, an output to be presented on display 918, and/or a command to be executed by the tablet computer 902 (e.g., raise the volume of the tablet computer 902) or sent to some other smart home device. Further, queries or commands may be submitted to cloud-based server system 908 via display 918, which may be a touchscreen. For instance, the tablet computer 902 may be used to control various smart home devices or home automation devices. Such commands may be sent directly by the tablet computer 902 to the device to be controlled or may be sent via cloud-based server system 908.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different embodiments and elements of the embodiments may be combined in a similar manner. Also, it should be emphasized that technology evolves and, thus, many of the elements are examples and should not be interpreted to limit the scope of the invention.

Specific details are given in the description to provide a thorough understanding of the embodiments. However, it will be understood by one of ordinary skill in the art that the embodiments may be practiced without these specific details. For example, well-known, processes, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing embodiments of the invention. Various changes may be made in the function and arrangement of elements without departing from the spirit and scope of the invention.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Having described several embodiments, it will be recognized by those of skill in the art that various modifications, alternative constructions, and equivalents may be used without departing from the spirit of the invention. For example, the above elements may merely be a component of a larger system, wherein other rules may take precedence over or otherwise modify the application of the invention. Also, a number of steps may be undertaken before, during, or after the above elements are considered. Accordingly, the above description should not be taken as limiting the scope of the invention.

1. A spring-loaded pin, comprising:
a body defining a housing, the housing having a first end and a second end;
a spring, located within the housing, the spring having a first end and a second end abutted against the second end of the housing;
a ball, the ball supported by the first end of the spring and located within the housing; and
a plunger, the plunger having a first portion and a second portion including a bias cut surface with respect to a longitudinal axis defined by the housing, wherein
the second portion of the plunger abuts a portion of the ball opposite from the first end of the spring.

2. The spring-loaded pin of claim 1, wherein a ratio of a diameter of the ball to a diameter of the housing is between 0.89 to 0.95.

3. The spring-loaded pin of claim 1, wherein the spring applies force to the ball and the plunger such that the plunger protrudes from the housing.

4. The spring-loaded pin of claim 1, wherein the plunger includes a flange portion, wherein the flange portion of the plunger forced by the spring abuts against a peripheral portion of the first end of the housing.

5. The spring-loaded pin of claim 1, wherein the ball comprises copper, and wherein the housing comprises brass.

6. The spring-loaded pin of claim 1, wherein the bias cut surface of the plunger is within a range of 12 degrees to 18 degrees.

7. The spring-loaded pin of claim 1, wherein the spring does not have a coating.

8. The spring-loaded pin of claim 2, wherein the diameter of the ball is in a range of 1.05 mm to 1.15 mm.

9. The spring-loaded pin of claim 2, wherein the diameter of the housing is in a range of 1.18 mm to 1.22 mm.

10. A system comprising:
an electronic device,
a dock, wherein the electronic device is removably coupled to the dock, the dock comprising an array of spring-loaded pins, each spring-loaded pin comprising:
an insulated body defining a cylindrical housing, the cylindrical housing having a first end and a second end;
a spring, located within the housing, the spring having a first end and a second end abutted against the second end of the housing;
a ball, the ball supported by the first end of the spring and located within the housing; and
a plunger, the plunger having a first portion and a second portion including a bias cut surface with respect to a longitudinal axis defined by the housing, wherein
the second portion of the plunger abuts a portion of the ball opposite from the first end of the spring; and wherein
the array comprises at least two outer spring-loaded pins and at least two inner spring-loaded pins, the array providing lateral protection from short circuits.

11. The system of claim 10, wherein the at least two outer spring-loaded pins being associated with power; and
the at least two inner spring-loaded pins being associated with transferring data between the device and the dock.

12. The system of claim 10, wherein the at least two outer spring-loaded pins being associated with transferring data between the device and the dock; and
the at least two inner spring-loaded pins being associated with power.

13. The system of claim 10, wherein the ball comprises copper.

14. The system of claim 10, wherein the housing comprises brass.

15. The system of claim 10, wherein a ratio of a diameter of the ball to a diameter of the housing is between 0.89 to 0.95.

16. The system of claim 10, wherein the bias cut surface of the plunger is within a range of 12 degrees to 18 degrees.

17. The system of claim 10, further comprising a molding for facilitating alignment of the array of spring-loaded pins.

18. The system of claim 10, further comprising an intermediate layer between the array of spring-loaded pins and the electronic device.

19. The system of claim 10, further comprising a plurality of contact pads located on the electronic device.

20. The system of claim 19, wherein a number of contact pads is equal to a number of spring-loaded pins.
